(19) United States
(12) Patent Application Publication
(10) Pub. No.: US 2012/0024804 A1
(43) Pub. Date: Feb. 2, 2012

(54) Monitor Stand Allowing Various Types of Motion

(76) Inventor: Jerry Moscovitch, Toronto (CA)

(21) Appl. No.: 13/193,306

(22) Filed: Jul. 28, 2011

Related U.S. Application Data
(60) Provisional application No. 61/368,355, filed on Jul. 28, 2010.

(51) Int. Cl. H05K 7/00; F16M 11/22

(52) U.S. Cl. 211/26; 248/158

(57) ABSTRACT

Described herein is a stand for supporting at least one computer monitor. The stand includes an upper support and a base structure connected thereto. The base structure includes a first base member having a curved surface, a bottom portion of the upper support adapted for sliding along the curved surface resulting in tilting of the upper support. The base structure also includes a second base member coupled to the first base member to allow the first base member and the upper support to rotate about an axis substantially perpendicular to the horizontal surface. The base structure further includes a third base member coupled to the second base member to allow the second base member to translate forward and backward with respect to the third base member.

### CROSS-REFERENCES TO RELATED APPLICATIONS

This application claims priority to U.S. provisional application No. 61/368,355, filed on Jul. 28, 2010.

### FIELD OF THE INVENTION

This invention relates to support structures for computer monitors, and more specifically to stands that allow various types of motion of the monitors supported therefrom.

### BACKGROUND OF THE INVENTION

The use of multi-monitor computer systems, where more than one monitor is coupled to a computer and supported by a support structure has increased in recent years. A multi-monitor computer system can be used to create the illusion of a larger screen, thereby allowing a user to view a large single file over several displays. Alternatively, the user may view individual applications on individual screens (for example, one screen may display a Web Browser and a second a spreadsheet of financial data).

For efficiency and comfort, it is desirable to be able to position the monitors in various positions while in use.

### SUMMARY OF THE INVENTION

Described herein is a stand for supporting at least one computer monitor. The stand includes an upper support and a base structure connected to the upper support and adapted to rest on a horizontal surface.

The base structure includes a first base member having a curved surface, a bottom portion of the upper support adapted for sliding along the curved surface resulting in tilting of the upper support. The base structure also includes a second base member coupled to the first base member to allow the first base member and the upper support to rotate about an axis substantially perpendicular to the horizontal surface. The base structure further includes a third base member coupled to the second base member to allow the second base member to translate forward and backward with respect to the third base member.

### BRIEF DESCRIPTION OF THE DRAWINGS

The various advantages of the invention will become apparent to one skilled in the art by reading the following specification and by referencing the following drawings.

FIG. 1A shows a stand for supporting at least one monitor, according to the principles of the present invention;

FIG. 1B shows the stand of FIG. 1A with the monitors removed;

FIG. 2A shows the stand of FIG. 1A with the upper support in a first tilted position;

FIG. 2B shows the stand of FIG. 1A with the upper support in a second tilted position;

FIG. 2C shows a section A-A of FIG. 2A;

FIG. 2D shows an exploded view of part of FIG. 2A;

FIG. 3A shows the stand of FIG. 1A with the upper support in a first rotated position;

FIG. 3B shows the stand of FIG. 1A with the upper support in a second rotated position;

FIG. 3C shows a section C-C of FIG. 3A;

FIG. 4A shows the stand of FIG. 1A with the upper support in a first translated position;

FIG. 4B shows the stand of FIG. 1A with the upper support in a second translated position;

FIG. 4C shows a section D-D of FIG. 4B;

FIG. 5 shows a different embodiment of a stand that permits tilting and rotation of monitors, according to the principles of the present invention;

FIG. 6 shows a different embodiment of a stand that permits rotation and translation of monitors, according to the principles of the present invention; and

FIG. 7 shows a different embodiment of a stand that permits tilting and translation of monitors, according to the principles of the present invention.

### DETAILED DESCRIPTION OF THE INVENTION

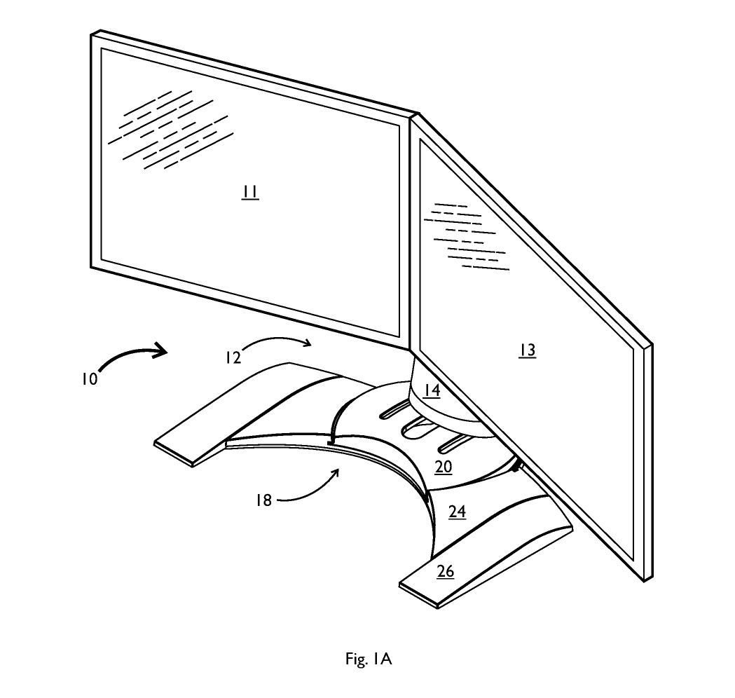

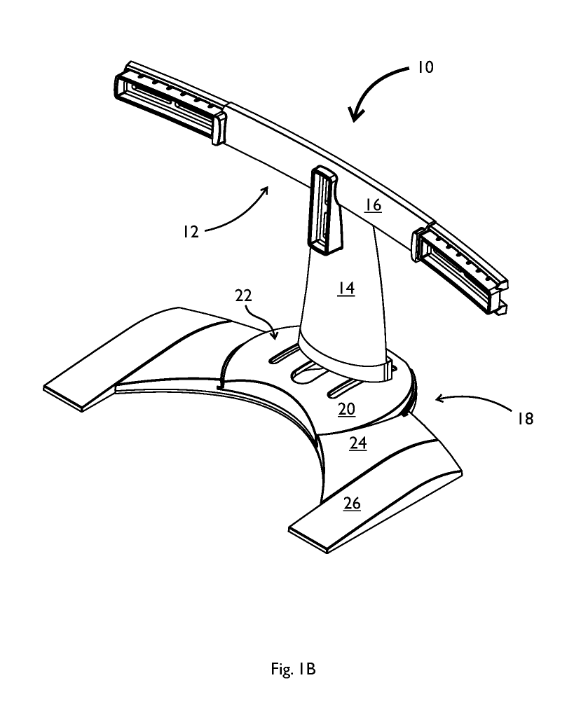

FIGS. 1A-B show a stand 10 for supporting at least one monitor 11, 13. FIG. 1A shows the stand with the monitors 11, 13 attached, and FIG. 1B shows the stand 10 with the monitors 11, 13 removed. The stand 10 includes an upper support 12. The upper support 12 shown in FIGS. 1A-B has a column 14 and a horizontal arm 16 that extends on either side of the column 14.

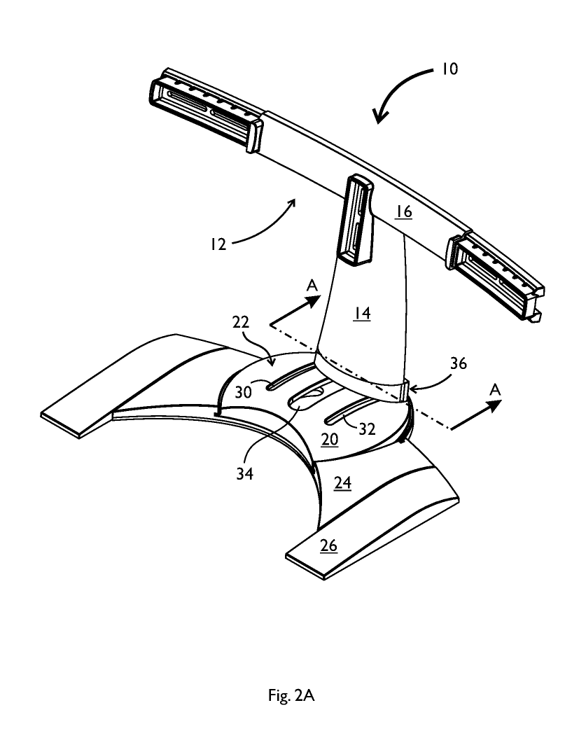

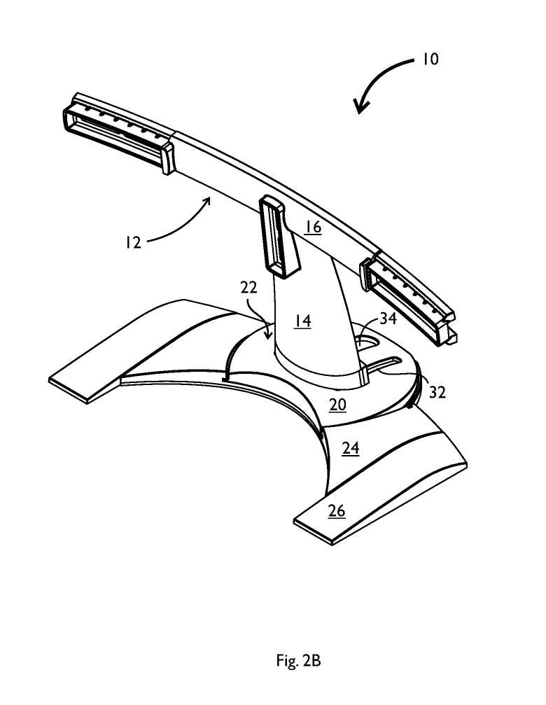

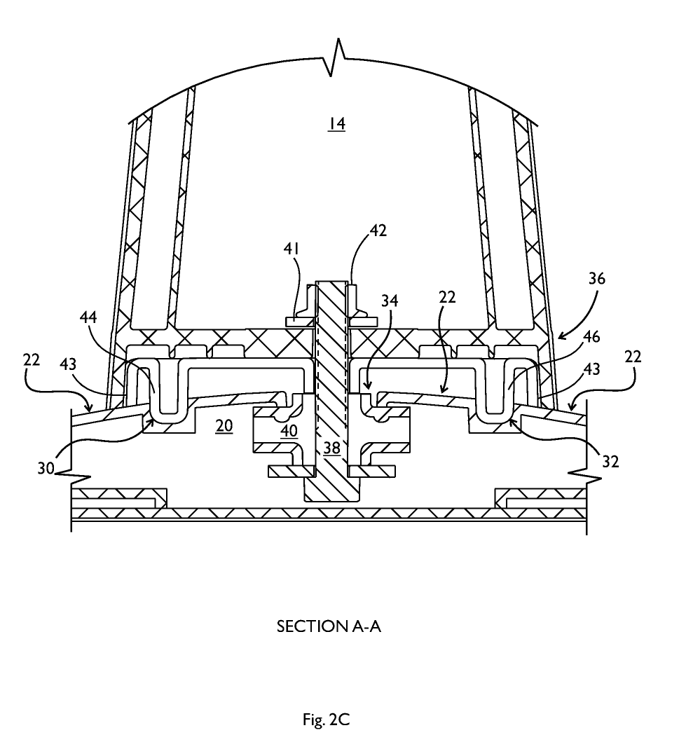

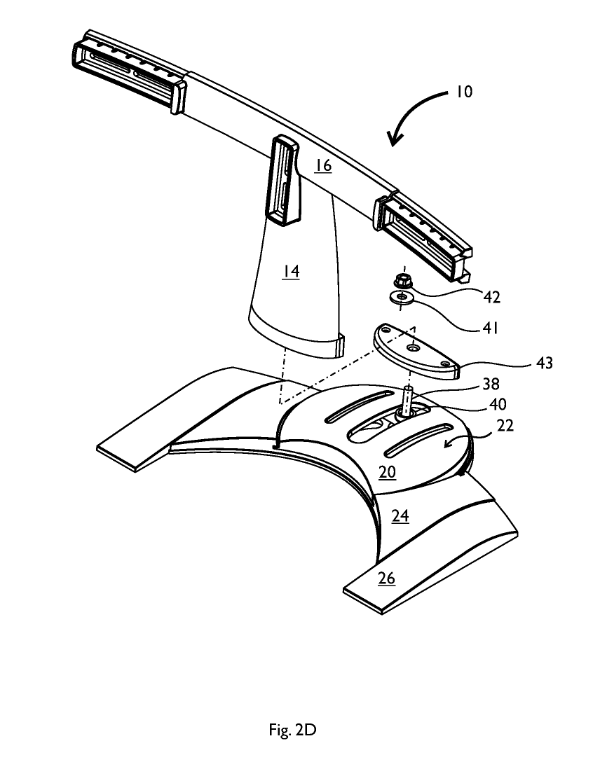

The stand 10 includes a base structure 18 connected to the column 14 of the upper support 12. The base structure 18 is adapted to rest on a horizontal surface, such as a desk. The base structure 18 includes a first base member 20 having a curved surface 22 (the curvature on the curved surface 22 is apparent in FIG. 2C), a second base member 24 coupled to the first base member 20, and a third base member 26 coupled to the second base member 24.

As described in more detail below, a lower portion of the upper support 12 slides along the curved surface 22 resulting in tilting of the upper support 12. The second base member 24 is coupled to the first base member 20 to allow the first base member 20 and the upper support 12 to rotate about an axis substantially perpendicular to the horizontal surface. The third base member 26 is coupled to the second base member 24 to allow the second base member 24 to translate forward and backward with respect to the third base member 26.

Advantageously, the monitors 11, 13 have three degrees of freedom associated with tilting, achieved using structure near the interface of the upper support 12 and first base member 20; rotation, achieved using structure near the interface of the first base member 20 and the second base member 24; and translation forward and backward, achieved using structure near the interface of the second base member 24 and the third base member 26. Consequently, a user can effectively position the monitors 11, 13 in a variety of desirable locations.

FIGS. 2A and 2B show two positions of the upper support 12 relative to the first base member 20. FIG. 2C shows a section A-A of FIG. 2A that makes apparent the curvature of the curved surface 22.

The first base member 20 includes a first outer slot 30, a second outer slot 32 and a middle slot 34 therebetween. A bolt 38 is inserted into the middle slot 34 at the bottom portion 36 of the upper support 12 after a bushing 40 is inserted into the bolt 38. A washer 41 is placed on the bolt 38 and a nut 42 is screwed on the bolt 38. The nut 42 is screwed on above the first base member 20 for attaching the first base member 20 to the upper support 12. Referring to FIG. 2D, which is an exploded view of part of FIG. 2A, an insert part 43 of the bottom portion 36 that is in contact with the curved surface 22 fits on the curved surface 22.

The upper support 12 further includes a first pin 44 and a second pin 46 at the bottom thereof. The first pin 44 is inserted into the first slot 30 and the second pin 46 is inserted into the second slot 32.

The insert part 43 of the bottom portion 36 of the upper support 12 slides along the curved surface 22. Due to the curvature of the curved surface 22, this sliding of the upper support 12 along the curved surface 22 results in various levels of tilting of the upper support 12 and of the monitors 11, 13 connected thereto. The bolt 38 remains stationary with respect to the column 14 as the column 14 tilts.

By tightening or loosening the nut 42 and by using various materials to manufacture the bushing 40, the curved surface 22 and the insert part 43 of the bottom portion 36 in contact with the curved surface 22, the amount of static and kinetic friction that obtains between the curved surface 22 and the insert part 43, and the bushing 40 and the bottom side of the curved surface 22 in contact therewith can be made to vary. As a result of varying the friction, the amount of load from the monitors 11, 13 that the upper support 12 can bear without flopping forward or backward, and the amount of force required to tilt the upper support 12 can be varied.

The first pin 44 and the second pin 46 guide the upper support 12 while tilting and prevent the upper support 12 from rotating about a vertical axis with respect to the first base member 20.

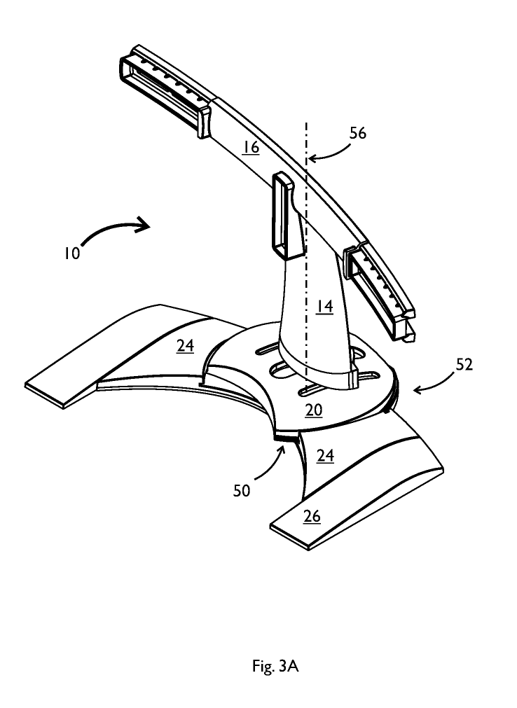

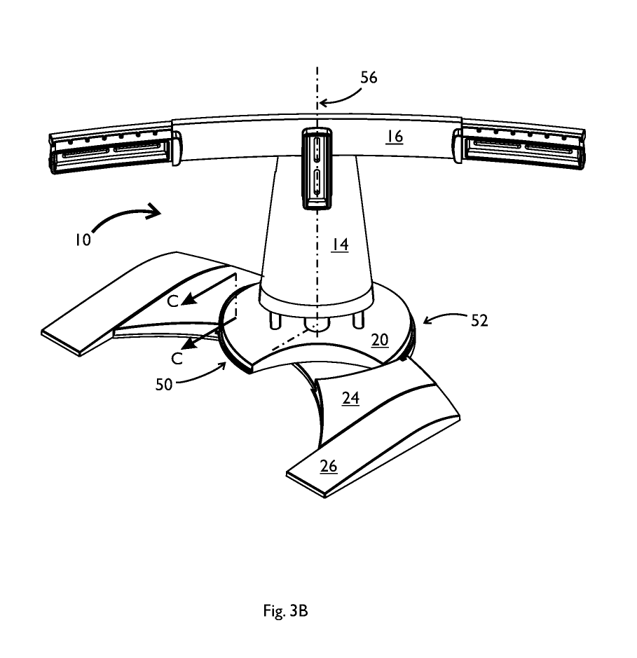

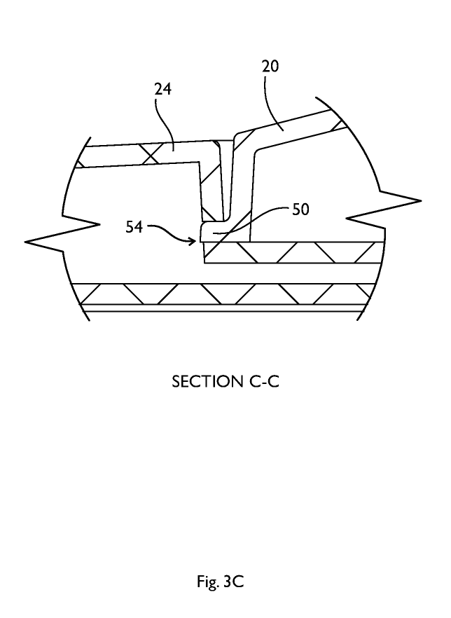

FIGS. 3A and 3B show two rotated positions of the first base member 20 relative to the second base member 24. FIG. 3C shows a section C-C of FIG. 3A. The first base member 20 includes a tongue 50 around a portion 52 of the perimeter of the first base member 20. The shape of the portion 52 is a circular arc. The second base member 24 includes a groove 54 into which the tongue 50 is inserted. The first base member 20 is thereby able to rotate with respect to the second base member 24 about an axis 56 that is substantially perpendicular to the horizontal surface on which the third base member 26 rests.

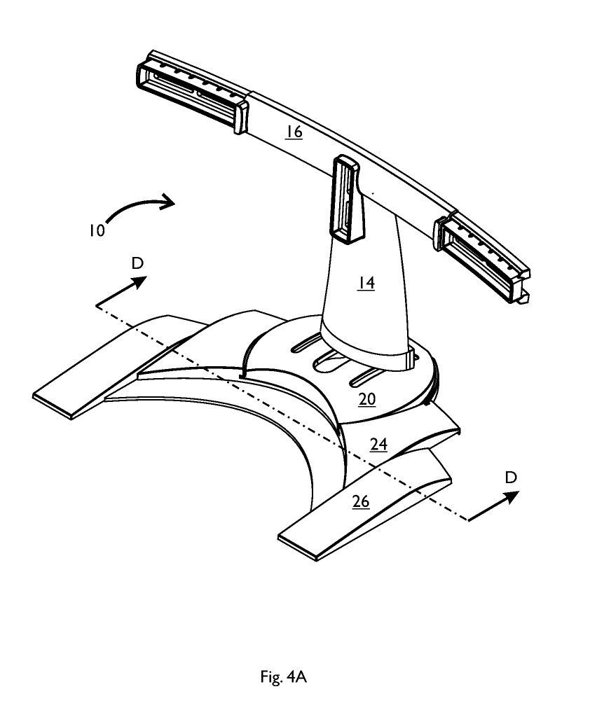

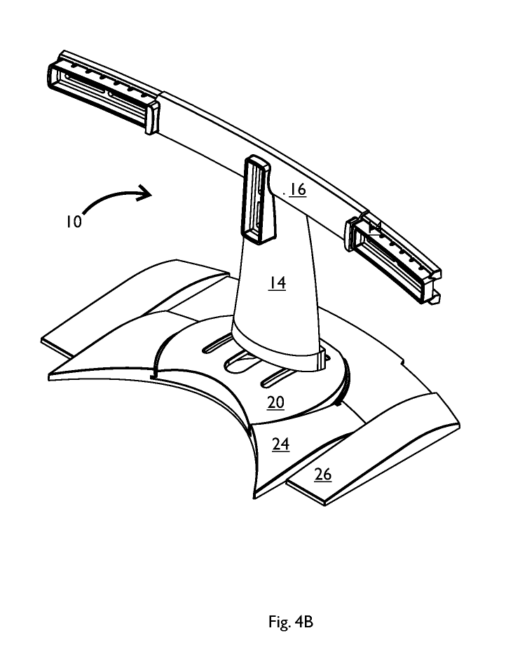

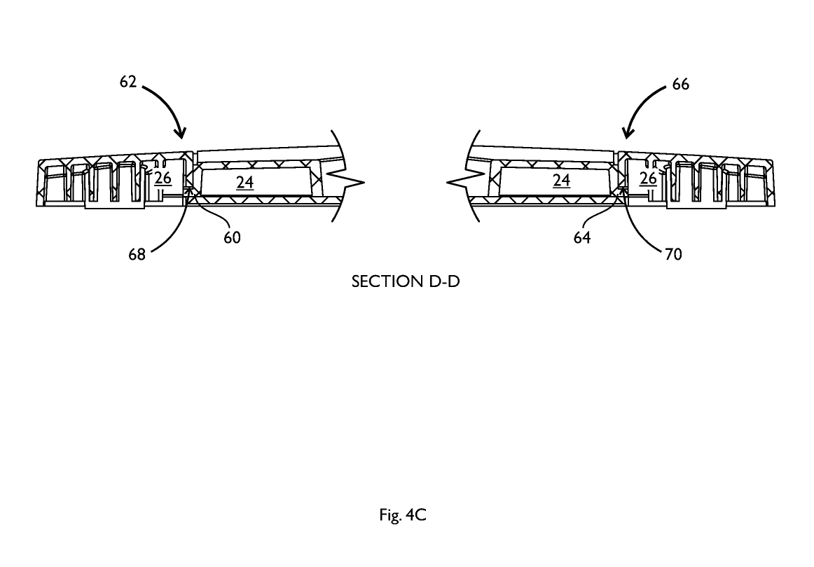

FIGS. 4A and 4B show two translated positions of the second base member 24 relative to the third base member 26. To achieve the function of allowing the second base member 24 to move backward and forward with respect to the third base member 26, a tongue and groove mechanism, similar to the tongue and groove mechanism that allows the first base member 20 to rotate, can be employed. However, in this case, when linear translation of the second base member is desired, the tongue and groove are linear instead of circular.

In particular, and with reference to FIG. 4C, which shows section D-D of FIG. 4B, the second base member 24 includes a first tongue 60 at one end 62 of the second base member 24. Similarly, the second base member 24 includes a second tongue 64 at another end 66 of the second base member 24. The third base member 26 includes a first groove 68 on one side and a second groove 70 on the opposite side.

The first tongue 60 of the second base member 24 fits into the first groove 68 of the third base member 26, and the second tongue 64 fits into the second groove 70 to allow the first tongue 60 and the second tongue 64 to slide forward and backward in the respective first groove 68 and second groove 70 to thereby permit the upper support 12 and the monitors 11, 13 to move forward and backward.

Other mechanisms could also permit the second base member to move forward and backward. For instance, various rolling bodies could assist in this motion. In one example, a carriage on the second base member could run on a rail on the third base member facilitated by ball bearings, as sometimes employed to allow drawers to be pulled out from cabinets.

It will be apparent that several modifications to the embodiments described above can be implemented without departing from the scope of the invention. For example, at the interface of the upper support and the first base member, the first and second base members, and the second and third base members various coupling mechanisms have been described that have involved a male component and a female component. To be specific, the male component was described as being disposed on one member, while the female component was described as being disposed on the other member. However, it is contemplated by the inventor that the location of the male and female components can be swapped where appropriate. For instance, instead of disposing the bolt 38 in the upper support 12, such that the bolt 38 remains stationary with respect to the column 14 as the column 14 tilts, and disposing the slots 30, 32, 34 in the first base member 20, it is possible to have the bolt in the first base member and the slots at the bottom of the upper support. In such case, the bolt would remain stationary with respect to the first base member and it would be the slots that moved to effect tilting. Likewise, instead of placing the tongue on the first member and the complimentary groove on the second base member to achieve rotation, the groove could reside on the first base member and the tongue on the second base member. Similarly, while an embodiment has been described above in which a tongue is disposed on the second base member and a mating groove is disposed in the third base member to achieve translation, the groove could instead be disposed on the third base member and the groove in the second base member.

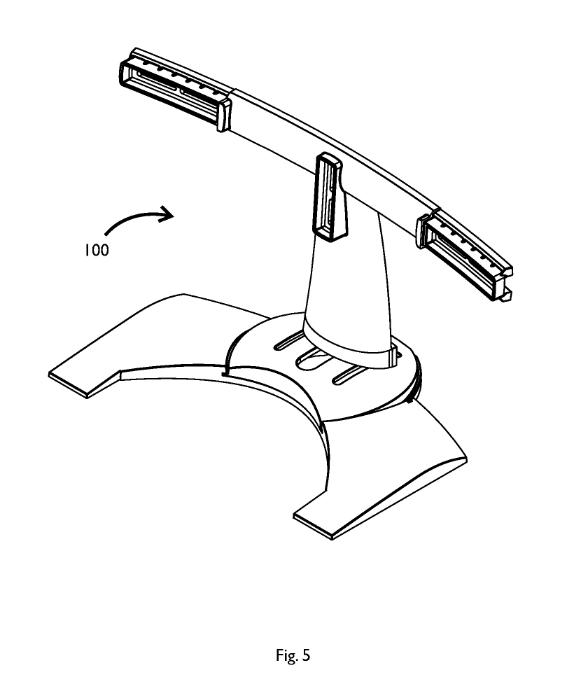

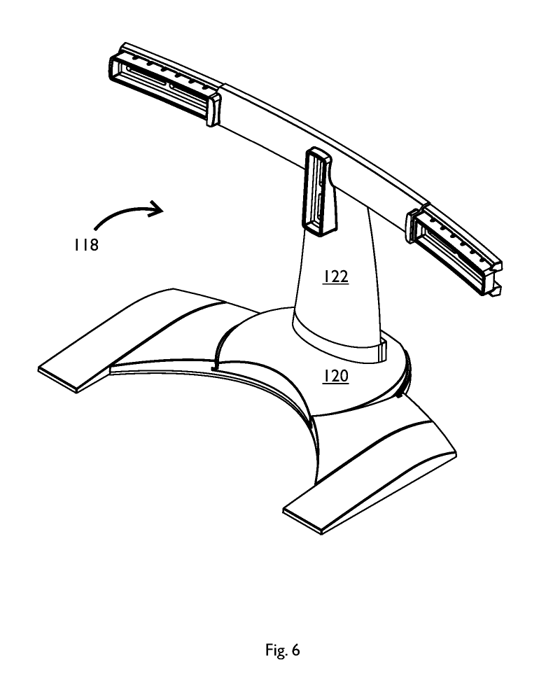

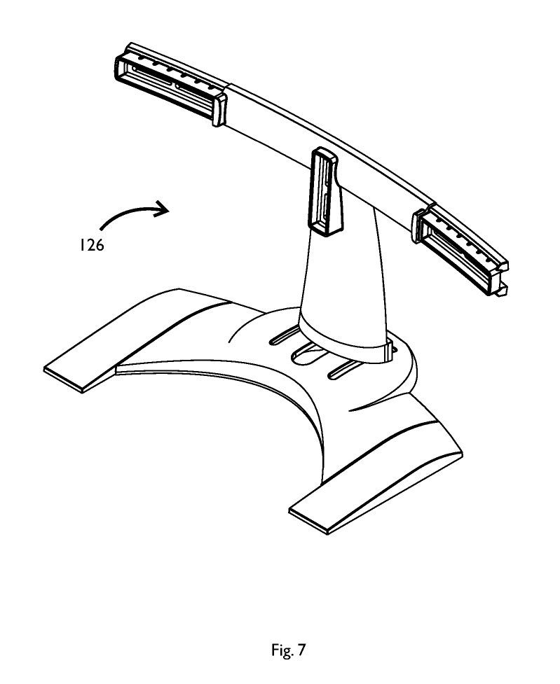

An embodiment of a monitor stand has been described above that has the capability to tilt, rotate and translate monitors. It should be understood, however, that in some embodiments, the monitor stand may only allow one or two of these types of motion, not all three. For instance, with reference to FIG. 5, a stand 100 for supporting at least one monitor is shown. The stand 100 permits tilting and rotation of monitors, but not translation forward and backwards. FIG. 6 shows a stand 118 that permits rotation and translation, but not tilting. In such case, a first base member 120 need have neither slots nor a curved top surface. Moreover, the first base member 120 and an upper support 122 are connected to each other and may be moulded as one piece. FIG. 7 shows a stand 126 that permits tilting and translation, but not rotation. It should be noted that reference to tilting, rotation and translation apply to these motions due to structural components near the base of the stand. Other types of motion of the monitors may be achieved via the connector of the monitors to the arm. For example, if a hinge connector is used to connect the monitors to the arm, the monitors may be able to rotate even if the base structure does not allow for rotation.

Also, although FIG. 1A shows two monitors, the principles of the present invention apply to a stand for one, two, or more than two monitors.

What is claimed is:

1. A stand for supporting at least one monitor, the stand comprising:
an upper support; and
a base structure connected to the upper support and adapted to rest on a horizontal surface, the base structure including
a first base member having a curved surface, a bottom portion of the upper support adapted for sliding along the curved surface resulting in tilting of the upper support, and
a second base member coupled to the first base member to allow the first base member and the upper support to rotate about an axis substantially perpendicular to the horizontal surface.

2. The stand of claim 1, further comprising a third base member coupled to the second base member to allow the second base member to translate forward and backward with respect to the third base member.

3. The stand of claim 2, wherein the upper support includes a column coupled to the base structure, and an arm attached to the column, said arm adapted to support a pair of monitors at either end of the arm.

4. The stand of claim 3, further comprising a nut above the first base member for attaching the first base member to the upper support, wherein:
the first base member includes a first outer slot, a second outer slot and a middle slot therebetween;
the upper support includes a bolt that is inserted through the middle slot to attach the upper support to the first base member by screwing above the first base member the nut on the bolt; and
a first pin and a second pin at the bottom of the upper support, the first pin being inserted into the first slot and the second pin being inserted into the second slot.

5. The stand of claim 4, wherein:
the first base member includes one of a tongue and a groove around a portion of the perimeter of the first base member; and
the second base member includes the other of the tongue and the groove, such that the tongue fits into the groove to thereby allow the first base member and the upper support to rotate about the axis.

6. The stand of claim 5, wherein:
the second base member includes one of a first groove and a first tongue at one end of the second base member;
the second base member includes one of a second groove and a second tongue at another end of the second base member;
the third base member includes the other of the first groove and the first tongue; and
the third base member includes the other of the second groove and second tongue, such that the first tongue fits into the first groove, and the second tongue fits into the second groove to allow the first tongue and the second tongue to slide forward and backward in the respective first groove and second groove to thereby permit the upper support to move forward and backward.

7. A stand for supporting at least one monitor, the stand comprising:
an upper support; and
a base structure connected to the upper support and adapted to rest on a horizontal surface, the base structure including
a first base member,
a second base member coupled to the first base member to allow the first base member and the upper support to rotate about an axis substantially perpendicular to the horizontal surface, and
a third base member coupled to the second base member to allow the second base member to translate forward and backward with respect to the third base member.

8. The stand of claim 7, wherein the first base member and the upper support are connected to each other and moulded as one piece.

9. A stand for supporting at least one monitor, the stand comprising:
an upper support; and
a base structure connected to the upper support and adapted to rest on a horizontal surface, the base structure including
a top base member having a curved surface, a bottom portion of the upper support adapted for sliding along the curved surface resulting in tilting of the upper support, and
a bottom base member coupled to the top base member to allow the top base member to translate forward and backward with respect to the bottom base member.

10. The stand of claim 9, wherein the upper support includes a column coupled to the base structure, and an arm attached to the column, said arm adapted to support a pair of monitors at either end of the arm.
